(19) United States
(12) Patent Application Publication
(10) Pub. No.: US 2026/0362631 A1
(43) Pub. Date: Nov. 12, 2026

(54) FAN ELECTRICAL CONNECTION STRUCTURE

(71) Applicant: ASIA VITAL COMPONENTS CO., LTD., New Taipei City (TW)

(72) Inventors: Sung-Wei Sun, New Taipei City (TW); Feng Liu, New Taipei City (TW); Yong Xiang, New Taipei City (TW); Cun-Bao Lyu, New Taipei City (TW); Bing Liu, New Taipei City (TW)

(21) Appl. No.: 19/238,710

(22) Filed: Jun. 16, 2025

(30) Foreign Application Priority Data
May 9, 2025 (TW) 114117572

(51) Int. Cl. H05K 7/20

(52) U.S. Cl. CPC H05K 7/20172

(57) ABSTRACT

A fan electrical connection structure includes a fan frame, at least one flexible circuit board, and at least one external circuit board. The fan frame is internally provided with an internal circuit board and includes an internal passage formed thereon. The flexible circuit board is set in the internal passage with an end electrically connected to the internal circuit board. The external circuit board is located on an outer side of the fan frame and is electrically connected to another end of the flexible circuit board. With the above arrangements, the assembling labor, time, and cost for arranging, organizing, and welding conductors one by one as required in a conventional fan can be saved; and the flexible circuit board can be protected against undesired separation from the fan frame due to pulling by an external force.

This application claims the priority benefit of Taiwan patent application number 114117572 filed on May 9, 2025, the disclosure of which is hereby incorporated by reference in its entirety.

### FIELD OF THE INVENTION

The present invention relates to a fan, and more particularly, to a fan electrical connection structure that can save the assembling labor, time, and cost for arranging, organizing, and welding fan conductors one by one.

### BACKGROUND OF THE INVENTION

A fan is a very common device used in system heat dissipation and is frequently employed in an electronic apparatus, such as a server or a computer, to provide the function of forced heat dissipation. Particularly, a dual-motor or a multi-motor fan can provide an even better heat dissipation effect. However, most conventional fans have a control circuit board that has to be outward extended and electrically connected to a motherboard of an external host for the purpose of signal transmission; and the control circuit board is electrically connected to the motherboard via a printed circuit board (PCB) with golden fingers. Conventionally, the PCB with golden fingers is fixed on the fan frame and the golden fingers are electrically connected and welded to conductors that are extended from the control circuit board in the fan frame. These conductors must first be arranged and organized in the fan frame, which is a highly difficult work. And, it is time and labor consuming to weld the conductors to the golden fingers one by one to largely increase the assembling cost.

It is therefore tried by the inventor to develop an improved fan electrical connection structure in order to overcome the problems of arranging and organizing conductors in the limited internal space of fan and welding the conductors to the golden fingers one by one.

### SUMMARY OF THE INVENTION

To effectively solve the above problems, a primary object of the present invention is to provide an improved fan electrical connection structure that utilizes a flexible circuit board to electrically connect an internal circuit board to an external circuit board, so as to efficiently utilize the limited internal space of a fan and save the assembling labor, time, and cost for arranging, organizing, and welding fan conductors one by one.

Another object of the present invention is to provide a fan electrical connection structure that includes a flexible circuit board being fitly attached to an outer side of a fan frame without the risk of undesired separation from the fan frame due to pulling by an external force.

A further object of the present invention is to provide a fan electrical connection structure that reduces the space needed for arranging and organizing fan conductors and the saved space can be used to increase the blade pitch of the fan or reduce the fan frame volume.

To achieve the above and other objects, the fan electrical connection structure according to the present invention includes a fan frame, at least one flexible circuit board, and at least one external circuit board. The fan frame is internally provided with an internal circuit board and includes an internal passage. The internal passage is communicable with an outer side and an inner side of the fan frame.

The flexible circuit board is set in the internal passage and has a first connection section formed at an end thereof for electrically connecting to the internal circuit board and a second connection section formed at another end thereof for electrically connecting to the external circuit board, such that the internal circuit board is electrically connectable to the external circuit board via the flexible circuit board.

In the fan electrical connection structure of the present invention, the flexible circuit board is used to electrically connect the internal and the external circuit board, and the external circuit board includes metal terminals for electrical connection to external devices. With these arrangements, it is able to effectively save the assembling labor, time, and cost for arranging, organizing, and welding conductors in the fan one by one and the flexible circuit board is protected against undesired separation from the fan frame due to pulling by an external force.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a fan electrical connection structure according to a first embodiment of the present invention;

FIG. 2 is an exploded perspective view of the fan electrical connection structure of FIG. 1 viewed from an angle different from that in FIG. 1;

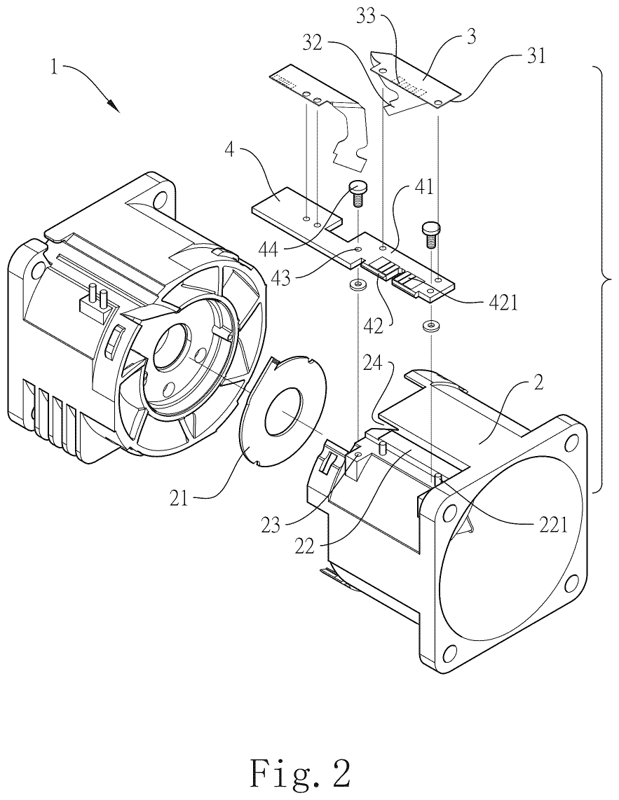

FIG. 3 is a cross sectional view of the fan electrical connection structure of FIG. 1; and

FIG. 4 is an assembled perspective view of a fan electrical connection structure according to a second embodiment of the present invention.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals.

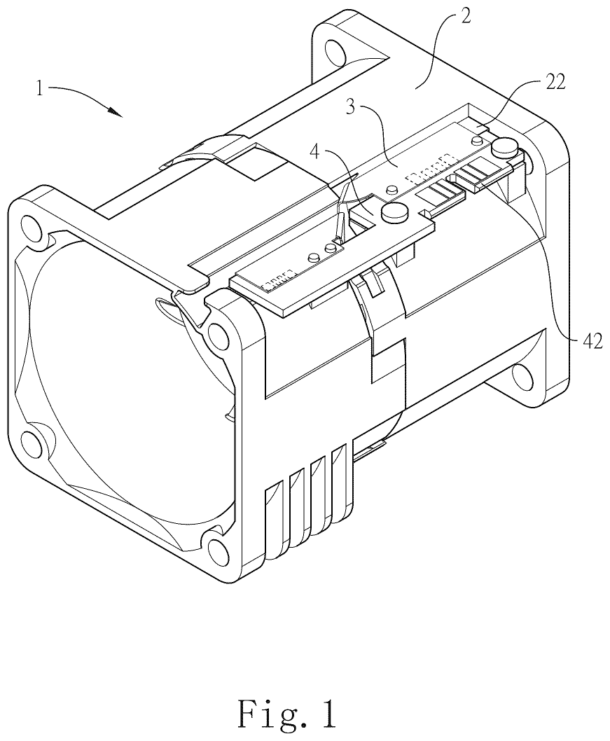

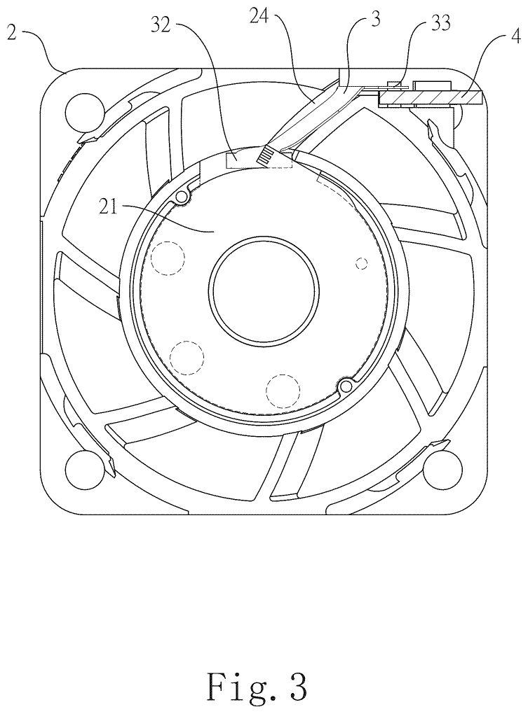

Please refer to FIG. 1, and 2, which are assembled and exploded perspective views, respectively, of a fan electrical connection structure 1 according to a first embodiment of the present invention; and to FIG. 3, which is a cross sectional view of the fan electrical connection structure of FIG. 1. As shown, the fan electrical connection structure 1 of the present invention includes a fan frame 2, at least one flexible circuit board 3, and at least one external circuit board 4.

The fan frame 2 is internally provided with at least one internal circuit board 21. In the first embodiment, the fan electrical connection structure 1 is illustrated as a dual-motor fan, that is, the illustrated fan frame 2 is configured for accommodating two motors therein, and the internal circuit board 21 is electrically connected to the two motors. However, it is understood the present invention is not necessarily limited to a dual-motor fan. The fan frame 2 is externally formed with an outer surface 22, on which at least one fixing bore 23 is provided. The fan frame 2 is also formed with an internal passage 24, which is radially communicable with an inner and an outer side of the fan frame 2. In other words, the internal passage 24 is radially outward extended to the external surface 22 and radially inward extended to the internal circuit board 21.

The flexible circuit board 3 is set in the internal passage 24 and has an end passing through the internal passage 24 to outward extend to the external surface 22. The flexible circuit board 3 is provided on one side surface with an adhesive layer 31 for fitly attaching to the external surface 22 of the fan frame 2. The external surface 22 may have a recess formed thereon for correspondingly receiving the flexible circuit board 3 therein. The external surface 22 may have at least one coupling post 221 provided thereon. The flexible circuit board 3 can pass the coupling posts 221 to be correspondingly held to the external surface 22. Further, the flexible circuit board 3 includes a first connection section 32 and a second connection section 33. And, the flexible circuit board 3 is electrically connected at the first connection section 32 to the internal circuit board 21.

The external circuit board 4 is located on the fan frame 2 and includes a first docking section 41 and a second docking section 42. The second docking section 42 has a plurality of metal terminals 421 provided thereon. The metal terminals 421 are metal electrical conductors formed through stamping. The external circuit board 4 further has at least one pair of docking holes 43 formed thereon. The docking holes 43 are located corresponding to and communicable with the fixing bores 23 and allow at least one fixing element 44 to extend therethrough. The flexible circuit board 3 is electrically connected at the second connection section 33 to the external circuit board 4, such that the external circuit board 4 is electrically connectable to the internal circuit board 21 via the flexible circuit board 3. And, the second docking section 42 is exposed from the fan frame 2.

To assemble the flexible circuit board 3 and the external circuit board 4 to the fan frame 2, first mount the external circuit board 4 on the fan frame 2 and align the docking holes 43 with the fixing bores 23. Then, extend the fixing elements 44 through the docking holes 43 to fix the external circuit board 4 on the fan frame 2. Thereafter, set the flexible circuit board 3 in the internal passage 24, such that the first connection section 32 is located corresponding to the internal circuit board 21 and the adhesive layer 31 of the flexible circuit board 3 is attached to the outer surface 22. Lastly, weld the first connection section 32 to the internal circuit board 21 and weld the second connection section 33 to the first docking section 41 of the external circuit board 4, such that the internal circuit board 21 is electrically connected via the flexible circuit board 3 to the external circuit board 4, allowing the internal circuit board 21 to be electrically connective and operable normally.

According to the fan electrical connection structure 1, the fan frame 2 is provided with an internal passage 24, and the flexible circuit board 3 can be electrically connected to the internal circuit board 21 and the external circuit board 4 via the internal passage 24. With these arrangements, the assembling labor, time, and cost for arranging, organizing, and welding all the conductors as required in conventional fans can be saved. Further, since the flexible circuit board 3 is fitly attached to the outer surface 22 of the fan frame 2, the flexible circuit board 3 is protected against undesired separation from the fan frame 2 due to pulling by an external force.

Further, another advantage of the fan electrical connection structure 1 according to the present invention is that the space inside the fan frame 2 initially required for arranging and organizing the conductors one by one can be saved. And, with the saved space, the fan blade pitch can be increased in the fan frame 2 of the same size. Alternatively, with the saved space, the fan frame 2 can be designed to have a reduced volume.

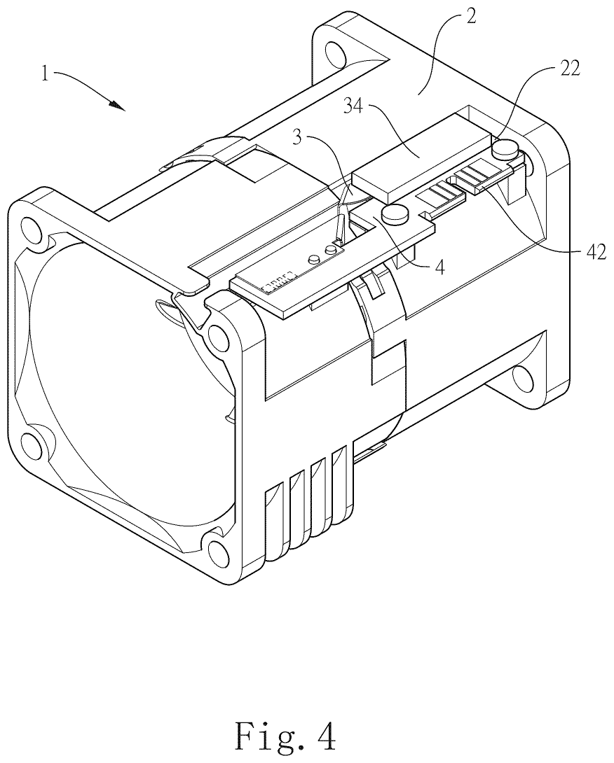

FIG. 4 is an assembled perspective view of a fan electrical connection structure 1 according to a second embodiment of the present invention. The second embodiment is different from the first one in further including a connector 34 provided on the second connection section 33. The connector 34 is associated with the fan frame 2 and the external circuit board 4 can be directly plugged into or unplugged from the connector 34, such that the internal circuit board 21 is electrically connected to the external circuit board 4 via the flexible circuit board 3 and the connector 34.

In conclusion, compared to the conventional fans, the present invention has the following advantages:
(1) Save the assembling labor, time, and cost initially required in the conventional fans to arrange, organize, and weld the conductors one by one;
(2) Effectively protect the flexible circuit board against undesired separation from the fan frame due to pulling by an external force; and
(3) Enable increased fan blade pitch or reduced fan frame volume.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A fan electrical connection structure, comprising:
a fan frame being internally provided with an internal circuit board and including an internal passage; and the internal passage being communicable with an outer side and an inner side of the fan frame; and
at least one flexible circuit board being set in the internal passage of the fan frame; each flexible circuit board including a first connection section electrically connected to the internal circuit board and a second connection section extending toward the outer side of the fan frame to be electrically connected to an external circuit board, such that the internal circuit board is electrically connected to the external circuit board via the flexible circuit board.

2. The fan electrical connection structure as claimed in claim 1, wherein the fan frame is externally formed with an outer surface, which is provided with a recess; and the flexible circuit board being received in the recess.

3. The fan electrical connection structure as claimed in claim 2, wherein the outer surface of the fan frame is provided with at least one fixing bore; and the external circuit board being extended through by at least one fixing element, and the fixing element being correspondingly extended through the fixing bore to fixedly hold the external circuit board to the fan frame.

4. The fan electrical connection structure as claimed in claim 1, wherein the second connection section has a connector provided thereon, and the flexible circuit board being electrically connected to the external circuit board via the connector.

5. The fan electrical connection structure as claimed in claim 1, wherein the external circuit board includes a first docking section and a second docking section; the first docking section being electrically connected to the second connection section, and the second docking section being exposed from the fan frame.

6. The fan electrical connection structure as claimed in claim 5, wherein the second docking section has a plurality of metal terminals provided thereon.

7. The fan electrical connection structure as claimed in claim 6, wherein the metal terminals are metal conductors formed through stamping.
